(19) United States
(12) Patent Application Publication
(10) Pub. No.: US 2020/0275528 A1
(43) Pub. Date: Aug. 27, 2020

(54) HEATER AND HEATER SYSTEM

(71) Applicant: KYOCERA Corporation, Kyoto-shi, Kyoto (JP)

(72) Inventor: Takeshi MUNEISHI, Kusatsu-shi, Shiga (JP)

(21) Appl. No.: 16/753,696

(22) PCT Filed: Oct. 26, 2018
(86) PCT No.: PCT/JP2018/039996

§ 371 Date: Apr. 3, 2020

(30) Foreign Application Priority Data
Oct. 27, 2017 (JP) 2017-208184

(51) Int. Cl. H05B 1/02; H01L 21/67; H05B 3/28

(52) U.S. Cl. CPC H05B 1/0233; H05B 2203/035; H05B 3/283; H01L 21/67248

(57) ABSTRACT

A heater includes a base body, a first resistance heating element, and a plurality of second resistance heating elements. The base body is an insulating member which includes a first surface and a second surface facing the first surface. The first resistance heating element extends along the first surface in an internal portion or on a surface of the base body. The second resistance heating elements are located on the first surface side or on the second surface side relative to the first resistance heating element and extend along the first surface in the internal portion or on the surface of the base body.

### TECHNICAL FIELD

The present disclosure relates to a heater and heater system.

### BACKGROUND ART

In semiconductor manufacturing systems and other technical fields, in order to heat semiconductor substrates (below, also referred to as “wafers”), a ceramic heater (below, sometimes also simply referred to as a “heater”) has been widely used. The heater for example has a disk-shaped ceramic substrate on the upper surface of which a wafer is placed and a resistance heating element which is buried in the ceramic substrate and extends with a suitable pattern (for example spiral) along the upper surface of the ceramic substrate.

Patent Literatures 1 and 2 disclose a heater provided with two resistance heating elements in a layered manner. In other words, a heater having two resistance heating elements at positions different from each other in a thickness direction of the ceramic substrate is disclosed. Patent Literatures 3 and 4 disclose a heater having a plurality of resistance heating elements at the same positions as each other in the thickness direction of the ceramic substrate. Patent Literature 5 discloses a heater which supplies a first power to all of one resistance heating element and supplies a second power to a portion of the resistance heating element superimposed on the first power.

### CITATION LIST

### Patent Literature

Patent Literature 1: Japanese Patent Publication No. 5-326112

Patent Literature 2: Japanese Patent Publication No. 9-270454

Patent Literature 3: Japanese Patent Publication No. 2001-135460

Patent Literature 4: Japanese Patent Publication No. 2005-166451

Patent Literature 5: International Patent Publication No. 2017/188189

### SUMMARY OF INVENTION

A heater according to one aspect of the present disclosure includes a base body, a first resistance heating element, and second resistance heating elements. The base body is an insulating member which includes a first surface and a second surface facing the first surface. The first resistance heating element extends along the first surface in an internal portion or on a surface of the base body. The second resistance heating elements are located on the first surface side or on the second surface side relative to the first resistance heating element and extend along the first surface in the internal portion or on the surface of the base body.

A heater system according to one aspect of the present disclosure includes the above heater, a first driving part which supplies power to the first resistance heating element, and a second driving part which individually supplies power to the plurality of second resistance heating elements.

### BRIEF DESCRIPTION OF DRAWINGS

FIG. 1 is a schematic view showing the configuration of a heater system according to an embodiment.

FIG. 2 is a disassembled perspective view of a heater in the heater system in FIG. 1.

FIG. 3 is a plan view showing an internal portion of the heater in FIG. 2.

FIG. 4 is a cross-sectional view taken along the IV-IV line in FIG. 3.

FIG. 5A and FIG. 5B are conceptual views showing an example of temperature control in the heater system in FIG. 1.

FIG. 6 is a block diagram showing the configuration of a signal processing system in the heater system in FIG. 1 from a viewpoint of the function.

FIG. 7 is a circuit diagram showing an example of the hardware configuration relating to the power supply in the signal processing system in FIG. 6.

FIG. 8 is a circuit diagram showing an example of the hardware configuration relating to temperature measurement in the signal processing system in FIG. 6.

FIG. 9 are timing charts showing the operation in the signal processing system in FIG. 6.

FIG. 10 is a circuit diagram showing the configuration of a principal part in a heater system in a second embodiment.

FIG. 11 are timing charts showing the operation in the heater system in FIG. 10.

FIG. 12 is a circuit diagram showing the configuration of the principal part in a heater system in a third embodiment.

FIG. 13A, and FIG. 13B are conceptual views and a timing chart showing the operation in the heater system in FIG. 12.

FIG. 14A, and FIG. 14B are cross-sectional views showing various modifications.

FIG. 15A is a view showing an example of application to which the heater system in the present disclosure is applied, and FIG. 15B is a view for explaining details of the example of application in FIG. 15A.

FIG. 16 is a view for explaining a modification.

### DESCRIPTION OF EMBODIMENTS

Below, a heater and heater system according to embodiments of the present disclosure will be explained with reference to the drawings. However, the drawings referred to in the following explanation are schematic ones for convenience of explanation. Accordingly, details will be sometimes omitted. Further, dimensions and ratios do not always coincide with the actual ones. Further, the heater and heater system may be further provided with known components which are not shown in the drawings as well.

Further, in the second and following embodiments, configurations the same as the configurations in the previously explained embodiments are assigned the same notations as the notations attached to the configurations in the previously explained embodiments. Further, sometimes explanations will be omitted. Even in a case where notations which are different from the notations attached to the configurations in the previously explained embodiments are attached to configurations corresponding (similar) to the configurations in the previously explained embodiments, matters which are not particularly explained may be made the same as the configurations in the previously explained embodiments.

### First Embodiment

### (Heater System)

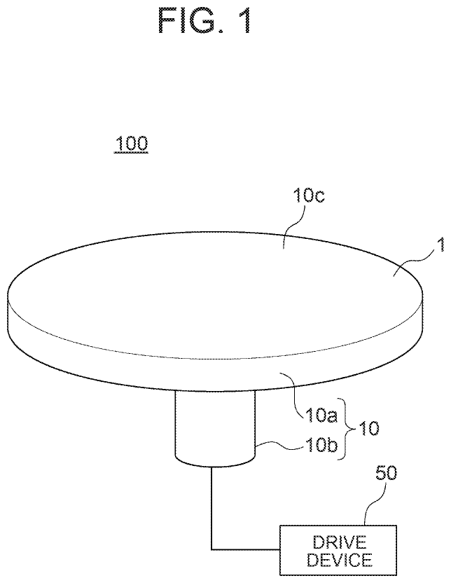

FIG. 1 is a schematic view showing the configuration of a heater system 100 according to an embodiment.

The heater system 100 has a heater 10 and a drive device 50 which drives the heater 10. Below, they will be explained in order.

Note that, the heater 10 does not always have to be used with the upper part in the drawing in FIG. 1 as the actual upper part. In the following description, for convenience, the upper part in the drawing in FIG. 1 will be defined as the actual upper part, and the “upper surface”, “lower surface”, and other terms will be sometimes used. Note that, for example, the upper surface is a first surface, and the lower surface is a second surface.

(Heater)

The heater 10, for example, has a substantially plate-shaped (disk-shaped in the example shown) heater body 10a and a pipe 10b extending downward from the heater body 10a.

In the heater body 10a, as an example of the heated object, a wafer is placed on the upper surface 10c. This is a portion directly contributing to heating of the wafer. The pipe 10b is for example a portion contributing to support of the heater body 10a and/or protection of cables (not shown) connected to the heater body 10a. Note that, the heater may be defined by only the heater body 10a excluding the pipe 10b as well.

The upper surface 10c and lower surface (notation is omitted) of the heater body 10a are for example substantially flat surfaces. The planar shape and various dimensions of the heater body 10a may be suitably set considering the shape, dimensions, etc. of the heated object. For example, the planar shape is circular (example shown) or rectangular. When showing an example of the dimensions, the diameter is 20 cm to 30 cm, and the thickness is 5 mm to 30 mm.

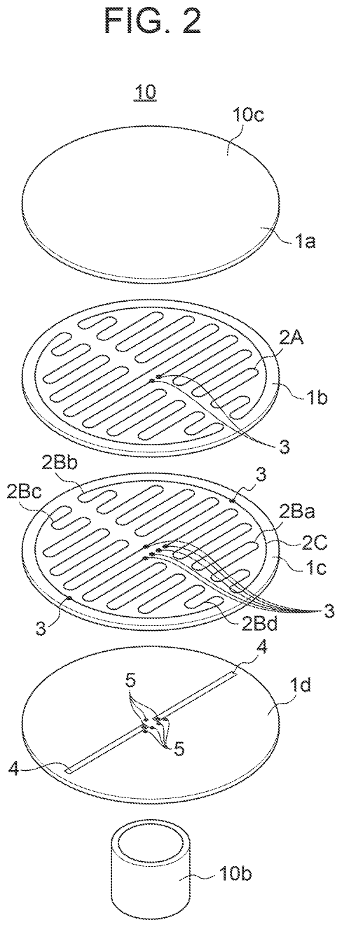

The pipe 10b is a hollow member (see FIG. 2 too) that is opened in the upper and lower parts (the two sides of the axial direction). The shapes of the lateral cross-section (cross-section perpendicular to the axial direction) and longitudinal cross-section (cross-section parallel to the axial direction) thereof may be suitably set. Further, the dimensions of the pipe 10b may be suitably set.

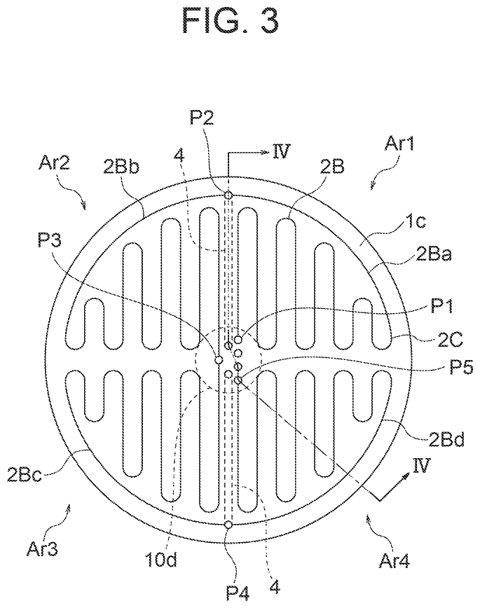

In a plane perspective, a region defined by an inner edge of the pipe 10b in the heater body 10a becomes a terminal arrangement region 10d (see FIG. 3) in which a plurality of terminals 5 which will be explained later (see FIG. 2) are arranged. The plurality of terminals 5 are exposed from the lower surface of the heater body 10a to the outside of the heater body 10a.

In the pipe 10b, a not shown plurality of cables are inserted. The plurality of cables are connected at single ends to the plurality of terminals 5 and are connected at the other ends to the drive device 50. Due to this, the heater body 10a and the drive device 50 are electrically connected.

(Internal Structure of Heater Body)

FIG. 2 is a disassembled perspective view of the heater 10. Note that, the completed heater 10 or heater body 10a is for example integrally formed so that disassembly is impossible. That is, it is not necessary for it to be able to be disassembled as in the disassembled perspective view in FIG. 2.

The heater body 10a is provided with an insulating base body 1 (for notation, see FIG. 1, configured by 1a, 1b, 1c, and 1d in FIG. 2), resistance heating elements (2A, 2Ba, 2Bb, 2Bc, and 2Bd, sometimes not differentiated and will be simply referred to as “resistance heating elements 2”) buried in the base body 1, and various conductors for supplying power to the resistance heating elements 2. The various conductors are for example connection conductors 3, wiring 4, and terminals 5. By current flowing in the resistance heating elements 2, heat is generated according to Joule's law whereby in turn the wafer placed on the upper surface 10c of the base body 1 is heated.

(Base Body)

The outer shape of the base body 1 forms the outer shape of the heater body 10a. Accordingly, the above explanation concerning the shape and dimensions of the heater body 10a may be grasped as an explanation of the outer shape and dimensions of the base body 1 as it is.

The material for the base body 1 is for example a ceramic. Accordingly, the heater 10 is a so-called ceramic heater. The ceramic is for example a sintered body containing as principal ingredients aluminum nitride (AlN), aluminum oxide (Al₂O₃), silicon carbide (SiC), silicon nitride (Si₃N₄), etc. Note that, an aluminum nitride ceramic containing aluminum nitride as the principal ingredient is for example excellent in corrosion resistance. Accordingly, configuring the base body 1 by an aluminum nitride ceramic is advantageous in for example use under a highly corrosive gas atmosphere.

In FIG. 2, the base body 1 is configured by a first ceramic layer 1a to a fourth ceramic layer 1d. Note that, the base body 1 may be prepared by materials forming the first ceramic layer 1a to fourth ceramic layer 1d (for example ceramic green sheets) stacked on each other. Further, the base body 1 may be prepared according to a method different from such a method. It may be grasped conceptually as being comprised of the first ceramic layer 1a to fourth ceramic layer 1d due to the presence of the resistance heating elements 2 etc. after completion.

The first ceramic layer 1a, second ceramic layer 1b, third ceramic layer 1c, and fourth ceramic layer 1d are stacked from the upper part in this order. Further, the first ceramic layer 1a configures the upper surface 10c of the heater body 10a. The fourth ceramic layer 1d configures the lower surface of the heater body 10a. Each of the first ceramic layer 1a to fourth ceramic layer 1d is for example a layer shape (plate shape) having substantially a constant thickness. The planar shape thereof is the same as the planar shape of the entire heater body 10a (base body 1) explained above. The thicknesses of the layers may be suitably set in accordance with the roles of the layers.

(Resistance Heating Elements)

The heater 10 has one first resistance heating element 2A and a plurality of (four in the example shown) second resistance heating elements 2Ba, 2Bb, 2Bc, and 2Bd (connected to each other in the present embodiment) as the resistance heating elements 2. Note that, in the following explanation, sometimes the second resistance heating elements 2Ba to 2Bd will not be differentiated and will be simply referred to as the “second resistance heating elements 2B”.

The resistance heating element 2A is configured by a conductor pattern positioned between the first ceramic layer 1a and the second ceramic layer 1b. The plurality of second resistance heating elements 2B are configured by conductor patterns positioned between the second ceramic layer 1b and the third ceramic layer 1c. That is, the plurality of second resistance heating elements 2B are positioned on a lower surface side of the heater 10 relative to the first resistance heating element 2A.

Each resistance heating element 2 extends along (parallel to) the upper surface 10c of the base body 1 and is substantially wire shaped. The route of extension thereof (pattern of the resistance heating element 2, the shape of the resistance heating element 2 when viewed on a plane) may be a spiral shape or meandering shape or another suitable shape. The pattern shown in the present disclosure is just one example.

The occupied region over each resistance heating element 2 spreads is for example defined by the smallest convex polygon including that resistance heating element 2. At this time, in a plane perspective, the occupied region of the first resistance heating element 2A and the occupied region of each resistance heating element 2B are for example superimposed on each other in at least part. In turn, the occupied region of the first resistance heating element 2A and the occupied region of the all of the plurality of second resistance heating elements 2 are superimposed on each other in at least part. For example, the occupied region of the first resistance heating element 2A and the occupied region of the all of the plurality of second resistance heating elements 2 are superimposed on each other in 80% or more of each. Note that, the occupied region of the all of the plurality of second resistance heating elements 2B may be a sum of the occupied regions of the second resistance heating elements 2B or may be the smallest convex polygon including the all of the plurality of second resistance heating elements 2. Further, the occupied region of the first resistance heating element 2A accounts for example 80% or more of the upper surface 10c (however, limited to a region capable of placing the wafer).

Further, the pattern of the first resistance heating element 2A and the pattern of the all of the plurality of second resistance heating elements 2B may be the same as each other or may be different from each other. Further, in a case where the two patterns are the same as each other, the two patterns may be superimposed on each other or may be offset from each other in a plane perspective. Note that, “superimposing” referred to here means superimposing in a narrower sense than superimposing of the occupied regions described above (state where the resistance heating elements 2 themselves are superimposed on each other).

In the explanation of the present embodiment, a state where the two patterns are the same as each other and are superimposed on each other will be taken as an example. However, even if saying the two patterns are the same as each other, for example, the two patterns are different from each other in part so that the plurality of conductors (3, 4, and/or 5) separately supplying power to the two patterns will not interfere with each other.

The material of the resistance heating elements 2 is a conductor (for example metal) generating heat by flow of current. The conductor may be suitably selected. It is for example tungsten (W), molybdenum (Mo), platinum (Pt), or indium (In) or alloys containing them as principal ingredients. Further, the material of the resistance heating elements 2 may be one obtained by firing a conductive paste containing the metal as described before as well. That is, the material of the resistance heating elements 2 may be one containing glass powder and/or ceramic powder or another additive (from another viewpoint, an inorganic insulator) as well.

As will be explained later, in the present embodiment, all or part of the resistance heating elements 2 are used also as sensor elements (thermistors) which detect the temperature. When use is made of tungsten or an alloy containing tungsten as a principal ingredient as the material of the resistance heating elements 2, for example, since tungsten has a relatively high resistance temperature coefficient, the precision of detection of the temperature is improved.

(Specific Patterns of Plurality of Second Resistance Heating Elements)

FIG. 3 is a plan view showing the upper surface of the third ceramic layer 1c.

The plurality of second resistance heating elements 2B are configured by a single continuous third resistance heating element 2C which is substantially divided into sections. Specifically, in the third resistance heating element 2C, its two ends and one or more (three in the example shown) midway positions become a first power supply part P1 to fifth power supply part P5 (below, sometimes they will be simply referred to as the “power supply parts P”) for supplying power to the third resistance heating element 2C. Due to this, it is possible to make currents flow with respect to a plurality of portions (plurality of second resistance heating elements 2B) in the single continuous third resistance heating element 2C independently from each other.

Note that, the power supply parts P closest to the two sides (P1 and P5) may be offset from the two ends of the third resistance heating element 2C as well. Further, regardless of any such offset, the terms may be defined so as to use the words “single continuous third resistance heating element 2C” for the part between the first power supply part P1 and the fifth power supply part P5 as well. In the following explanation, for convenience, the “two ends of the third resistance heating element 2C” and the “power supply parts P closest to the two sides” are assumed to be the same in meaning.

Further, the third resistance heating element 2C need not be specially configured in the power supply parts P (for example pad shapes or the like). It may be configured the same as the majority of the resistance heating elements 2. In FIG. 2 and FIG. 3, for convenience in clarifying the positions of the power supply parts P, via conductors passing through the third ceramic layer 1c are shown at the positions of the power supply parts P. The via conductors, as will be explained later, configure connection conductors 3 or terminals 5. Note that, the third resistance heating element 2C may be specially configured in the power supply parts P as well.

The third resistance heating element 2C for example extends from its one end (first power supply part P1) to the other end (fifth power supply part P5) without intersecting itself. The position and shape of the route may be suitably set. For example, the two ends of the third resistance heating element 2C fall in the terminal arrangement region 10d explained above.

Further, for example, the third resistance heating element 2C, when viewed on a plane, extends, in order, in the first area Ar1 to fourth area Ar4 (fan-shaped areas in the example shown, below, sometimes simply referred to as the “areas Ar”) obtained by dividing the base body 1 in a circumferential direction. Further, the plurality of second resistance heating elements 2Ba to 2Bd fall in the first area Ar1 to fourth area Ar4 in order. In the example shown, the number of parts the base body 1 is divided into is 4. Further, the base body 1 is equally divided.

Note that, the number of the plurality of areas Ar (from another viewpoint, the occupied regions of the plurality of second resistance heating elements 2B) divided into, the divided directions, divided positions, and the relationships of size of the same may be suitably set other than those described above. For example, in place of or addition to division in the circumferential direction as in the example shown, the regions may be divided in a radial direction or may be unequally divided. Further, the number of areas divided into may be smaller or larger than 4.

Also the routes of the resistance heating elements 2B in the areas Ar may be suitably set. In the example shown, the second resistance heating elements 2B substantially extend in zigzag manners (meandering states) in the areas Ar. Further, the second resistance heating elements 2B have portions extending along the outer edge of the base body 1 in addition to the zigzag portions described above.

(Specific Pattern of First Resistance Heating Element)

As already explained, in the explanation of the present embodiment, the case where the pattern of the first resistance heating element 2A and the pattern of all of the plurality of second resistance heating elements 2B are the same will be taken as an example. Accordingly, the explanation for the pattern of the third resistance heating element 2C described above may be applied to the first resistance heating element 2A. However, the first resistance heating element 2A has power supply parts P only at the two ends.

(Connection Conductors, Wiring, and Terminals)

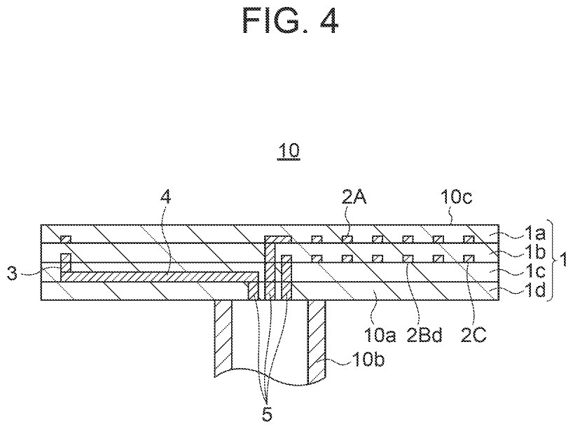

FIG. 4 is a cross-sectional view taken along the IV-IV line in FIG. 3.

The connection conductors 3, wiring 4, and terminals 5 shown in FIG. 2 to FIG. 4 are ones for supplying power to the resistance heating elements 2 and are provided in the base body 1. The wiring 4 for example becomes hierarchical wiring positioned in a lower layer relative to the first resistance heating element 2A and plurality of second resistance heating elements 2B and connects any of the plurality of power supply parts P and any of the plurality of terminals 5. The connection conductors 3 are interposed between the wiring 4 and the power supply parts P and contribute to connection of them. By the provision of such hierarchical wiring, for example, it becomes possible to connect any position (power supply part) of the resistance heating element 2 and a terminal 5 positioned at any position.

More specifically, for example, the terminals 5, as already explained, are exposed from the lower surface of the base body 1 to the outside of the base body 1 in a portion of the region on the center side in a planar view of the base body 1 constituting the terminal arrangement region 10d (FIG. 3). Further, for example, among the power supply parts P, ones positioned outside of the terminal arrangement region 10d (P2 and P4 in the present embodiment) are connected through the connection conductors 3 and wiring 4 to the terminals 5. On the other hand, the power supply parts P positioned in the terminal arrangement region 10d are for example directly connected to the terminals 5 without going through the wiring 4.

The connection conductors 3 for example include via conductors passing through a portion of the base body 1 (the third ceramic layer 1c in the present embodiment). Further, by positioning them right under the power supply parts P, they are connected to these power supply parts P. Note that, although not particularly shown, the connection conductors 3 may be divided into a plurality of via conductors which are arranged along the route of the resistance heating elements 2 in the direction in which the resistance heating elements 2 extend as well. By arranging them in this way, for example, it is possible to make a conduction area between the connection conductors 3 and the resistance heating elements 2 large and make the size of the connection conductors 3 in a width direction of the resistance heating element 2 small.

The wiring 4 is for example configured by a conductor pattern positioned between the third ceramic layer 1c and the fourth ceramic layer 1d. That is, the wiring 4 is buried in the base body 1. The dimensions and shape of the wiring 4 may be suitably set. In the example shown, the wiring 4 substantially extends straight in the radial direction of the base body 1 with a constant width.

Among the plurality of terminals 5, one connected to the wiring 4 is for example configured by a via conductor passing through the fourth ceramic layer 1d. Further, this terminal 5 is connected to the wiring 4 by being positioned right under the wiring 4 at substantially the end part of the wiring 4 on the side opposite to the connection conductor 3.

Among the plurality of terminals 5, ones directly connected to the second resistance heating elements 2B without going through the wiring 4 are for example configured by via conductors passing through the third ceramic layer 1c and fourth ceramic layer 1d. Further, the terminals 5 connected to the first resistance heating element 2A are for example configured by via conductors passing through the second ceramic layer 1b to fourth ceramic layer 1d. Further, these terminals 5 are connected to the power supply parts by being positioned right under the resistance heating elements 2. Note that, in these terminals 5, the material and/or shape of the portions passing through the second ceramic layer 1b and/or third ceramic layer 1c may be made the same as that of the connection conductors 3 positioned between the resistance heating elements 2 and the wiring 4.

The materials of the connection conductors 3, wiring 4, and terminals 5 may be suitable conductors (for example metal). For example, the materials of them are molybdenum (Mo), tungsten (W), tantalum (Ta), platinum (Pt), indium (In) or alloys containing them as principal ingredients. Further, the materials of the connection conductors 3, wiring 4 , and terminals 5 may be ones obtained by firing a conductive paste containing the metal as described before as well. That is, the materials of these conductors may be ones containing glass powder and/or ceramic powder as well. Further, the materials of them may be the same materials or different materials from the material of the resistance heating elements 2.

In the connection parts of the via conductors (connection conductors 3 and terminals 5) and the layer-shaped patterns (resistance heating elements 2 and wiring 4), from the viewpoint of the material or manufacturing process etc., the via conductors may be connected to the upper surface or lower surface of the layer-shaped pattern or the layer-shaped pattern may be connected to the peripheries of the via conductors. Such differentiation may be impossible as well. In the explanation of the present embodiment, for convenience, in any case, the explanation will be given conceptually grasping the connection conductors 3 and/or terminals 5 being connected to the upper surfaces or lower surfaces of the resistance heating elements 2 and wiring 4.

(Drive Device)

The drive device 50 shown in FIG. 1 is configured including for example a power supply circuit and a computer and the like. It converts power from a commercial power source to AC power and/or DC power having a suitable voltage and supplies the result to the heater 10 (plurality of terminals 5). The computer is for example configured by an IC (integrated circuit) and/or personal computer (PC). Further, the computer is provided with for example a CPU (central processing unit), ROM (read only memory), RAM (random access memory), and external memory device. By the CPU running a program stored in the ROM etc., various types of functional parts such as the control part are configured. Note that, the control part etc. may be configured by combining circuits performing predetermined computation processing as well. The processing carried out by the drive device 50 may be digital processing or may be analog processing.

(Control Method)

An outline of the control method in the heater system 100 will be explained.

The heater 10 has the first resistance heating element 2A and the plurality of second resistance heating elements 2B which are arranged in a stacked manner with respect to the first resistance heating element 2A, therefore the upper surface 10c can be heated by the total amount of heat generated by the two. In such a case, roles may be suitably allocated between the first resistance heating element 2A and the plurality of second resistance heating elements 2B.

For example, the majority of the amount of heat generated by the heater body 10a may be realized by the first resistance heating element 2A, while the temperature may be controlled for each of the areas Ar of the heater body 10a by the plurality of second resistance heating elements 2B. The local temperature control by the plurality of second resistance heating elements 2B for example may be utilized for making the temperature distribution in the heater body 10a uniform or, conversely, for making the heater body 10a generate a desired temperature gradient. Note that, in the following explanation, the case of making the temperature distribution uniform will be taken as an example.

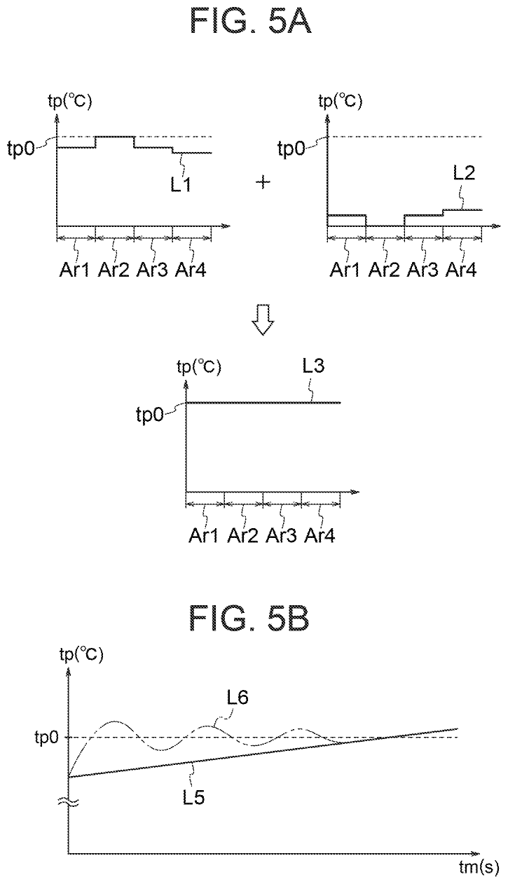

FIG. 5A are conceptual views showing the outline of the control method of the heater system 100 as described above.

In three graphs in FIG. 5A, the abscissas show the first area Ar1 to fourth area Ar4. The ordinates show the temperatures tp (° C.) of the upper surface 10c or the amounts of heat corresponding to the amounts of rise of the temperature tp. Note that, for convenience, in the explanation of the present disclosure, sometimes the amount of heat corresponding to the amount of rise of the temperature tp will be explained by the temperature tp (the strict meaning of the expressions will be ignored).

In the graph on the left side in an upper part in FIG. 5A, a line L1 indicates the temperature realized by the first resistance heating element 2A. In the graph on the right side in the upper part in FIG. 5A, a line L2 indicates the amount of rise of the temperature realized by the plurality of second resistance heating elements 2B. In the graph in a lower part in FIG. 5A, a line L3 indicates the temperature realized by both of the first resistance heating element 2A and the plurality of second resistance heating elements 2B.

The target temperature of the upper surface 10c is made tp0. As shown in the graph on the left side in the upper part in FIG. 5A, the first resistance heating element 2A is for example utilized for generating an amount of heat high enough to raise the temperature of the upper surface 10c up to substantially the target temperature tp0. However, due to manufacturing error of the heater 10, the environment in which the heater 10 is used, and other various circumstances, the temperatures in the plurality of areas Ar do not become the same as each other, but vary. Therefore, the first resistance heating element 2A is supplied with power which is for example large enough to make the detection temperature in the area having the highest temperature (the second area Ar2 in the example shown) among the plurality of areas Ar reach the target temperature tp0.

On the other hand, each of the second resistance heating elements 2B is supplied with power so that the detection temperature in the area Ar corresponding to itself converges to the target temperature tp0. From another viewpoint, as shown by the graph on the right side in the upper part in FIG. 5A, each of the second resistance heating elements 2B is supplied with power so as to generate the amount of heat corresponding to the temperature difference between the target temperature tp0 and the temperature realized by the first resistance heating element 2A in the area Ar corresponding to itself.

As a result, as shown in the graph in the lower part in FIG. 5A, the temperatures in all of the areas Ar converge to the target temperature tp0. That is, variation in the temperature distribution of the upper surface 10c is reduced.

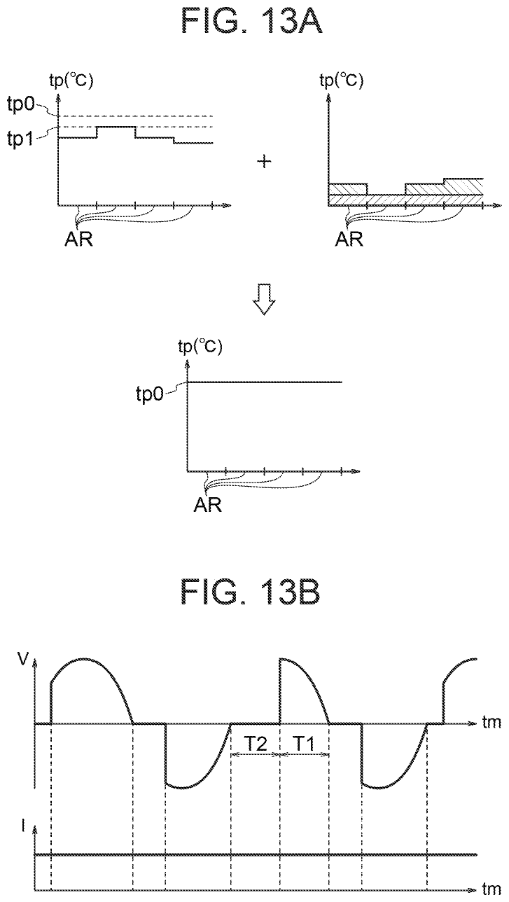

The first resistance heating element 2A may be supplied with power so as to generate an amount of heat high enough to realize a provisional target temperature (not shown here, see tp1 in FIG. 13A) which is lower than the target temperature tp0 as well. The provisional target temperature is for example made lower than the target temperature tp0 by a difference not less than the maximum value of variation of the temperature distribution by the first resistance heating element 2A. The first resistance heating element 2A is for example controlled so that a temperature obtained by subtracting the temperature difference between the target temperature tp0 and the provisional target temperature from the detection temperature converges to the provisional target temperature. As the detection temperature at this time, in place of the temperature in the area Ar with the highest temperature, the mean temperature of the upper surface 10c may be used as well.

On the other hand, each of the second resistance heating elements 2B, in the same way as that described above, is supplied with power so that the detection temperature in the area Ar corresponding to itself converges to the target temperature tp0. Due to this, the second resistance heating element 2B generates the amount of heat for raising the temperature in the area Ar from the provisional target temperature to the target temperature tp0 which is higher than this.

In the case where the detection temperature in the area Ar with the highest temperature converges to the target temperature tp0 by the first resistance heating element 2A, the temperatures in all of the areas Ar become close to the target temperature tp0 unless the variation of the temperature distribution due to the first resistance heating element 2A is unrealistically large relative to the target temperature tp0. That is, the amount of heat generation of any of the plurality of second resistance heating elements 2B becomes small. Accordingly, the power supplied to the first resistance heating element 2A becomes larger than the sum of the power supplied to the plurality of second resistance heating elements 2B.

Further, in the case where the amount of heat for realizing the provisional target temperature lower than the target temperature tp0 is generated by the first resistance heating element 2A, by setting the provisional target temperature, the relative relationship between the power supplied to the first resistance heating element 2A and the sum of the power supplied to the plurality of second resistance heating elements 2B can be suitably set. However, in this case as well, for example, the provisional target temperature is set so that the power supplied to the first resistance heating element 2A becomes larger than the sum of the power supplied to the plurality of second resistance heating elements 2B.

For example, the provisional target temperature is one by which the amount of rise from the reference temperature is 50% or more or 90% or more of the amount of rise from the reference temperature up to the target temperature tp0 (° C.). The reference temperature is for example room temperature (for example, set as 20° of the center value of ordinary temperature 20° C.±15° C. defined by the Japanese Industrial Standards). As one example, the target temperature tp0 is 650° C., and the provisional target temperature is 620° C.

FIG. 5B is a schematic view for explaining the relationships between the control by the first resistance heating element 2A and the control by the plurality of second resistance heating elements 2B regarding the response of feedback control of the temperature.

In this graph, the abscissa indicates the time. The ordinate indicates the temperature. A line L6 indicates a change along with time of the temperature when assuming that the temperature in the predetermined area Ar (for example the area Ar having the highest temperature) was feedback controlled by the first resistance heating element 2A and the plurality of second resistance heating elements 2B. Aline L5 indicates the change along with time of the temperature corresponding to the amount of heat generated by the first resistance heating element 2A in the predetermined area Ar described above in a case where the change along with time of the temperature indicated by the line L6 is obtained. Accordingly, the difference between the line L5 and the line L6 indicates the change along with time of the temperature corresponding to the amount of heat generated by the second resistance heating elements 2B in the above predetermined area Ar.

As shown in this graph, for example, the feedback control of the temperature by the plurality of second resistance heating elements 2B becomes better in response than the feedback control of the temperature by the first resistance heating element 2A. Due to this, for example, the temperature realized by the sum of the amounts of heat of the two types of the resistance heating elements 2 becomes easier to converge to the target temperature tp0. In other words, the possibility of divergence of the detection temperature due to mutual interference by the two types of control is reduced.

Note that, the response is for example a speed of making the detection value return to the target value. Accordingly, for example, when the detection value deviates from the target value, the shorter the time until the detection value returns to the target value (or a predetermined range including the target value at the center), the better the response. Further, in the response referred to here, the speed by which vibration of the detection value relative to the target value becomes small (magnitude of overshoot etc.) is not considered an issue.

The difference of response between the two may be suitably realized. For example, in the control of the plurality of second resistance heating elements 2B, a proportional gain may be made larger or a cycle for performing the feedback control may be made shorter relative to the control of the first resistance heating element 2A. That is, the two controls may be made different in parameters from each other. Further, for example, the control of the first resistance heating element 2A is made integral control or fuzzy control, while the control of the second resistance heating elements 2B may be made proportional control, PD (proportional differential) control, PI (proportional integral) control, or PID control, and the like. That is, the two controls may be different in the control method from each other as well.

(Specific Configuration of Drive Device)

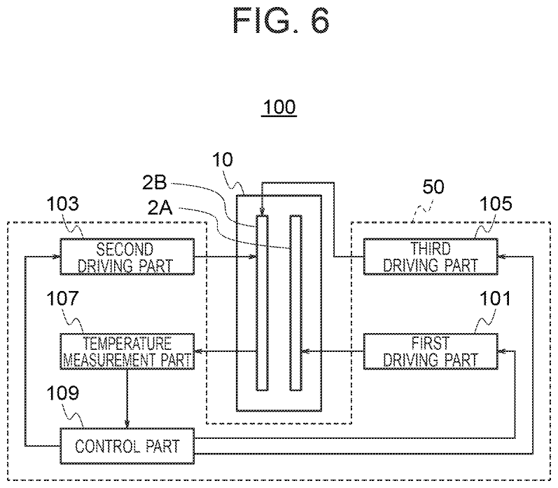

FIG. 6 is an example of a block diagram showing the configuration of the signal processing system in the heater system 100 from a functional viewpoint

The heater system 100, as already explained, has the heater 10 and drive device 50. The drive device 50 has a first driving part 101, second driving part 103, and third driving part 105 which supply power to the heater 10. Further, the drive device 50 has a temperature measurement part 107 which detects the temperature of the heater 10 and has a control part 109 which controls the operation of the driving parts (101, 103, and 105).

The first driving part 101 supplies power to the first resistance heating element 2A. The second driving part 103 individually supplies power to the plurality of second resistance heating elements 2B. The third driving part 105 commonly supplies power to all of the plurality of second resistance heating elements 2B.

Further, the first driving part 101 performs feedback control of the power which is supplied to the first resistance heating element 2A based on the temperature detected by the temperature measurement part 107. In the same way, the second driving part 103 performs feedback control of the power which is individually supplied to the second resistance heating elements 2B based on the temperature detected by the temperature measurement part 107.

The hardware configurations for realizing such various functional parts (101, 103, 105, 107, and 109) may be suitable ones. Further, the various functional parts may be constructed in part or all on the mutually same hardware (for example the same IC or same PC) as well. Further, each of the functional parts further may have a plurality of functional parts in a lower significant concept. Single portions of the plurality of functional parts in the lower significant concept may be shared by higher significant functional parts (101, 103, 105, 107, and 109) as well.

(Hardware Configuration According to Power Supply)

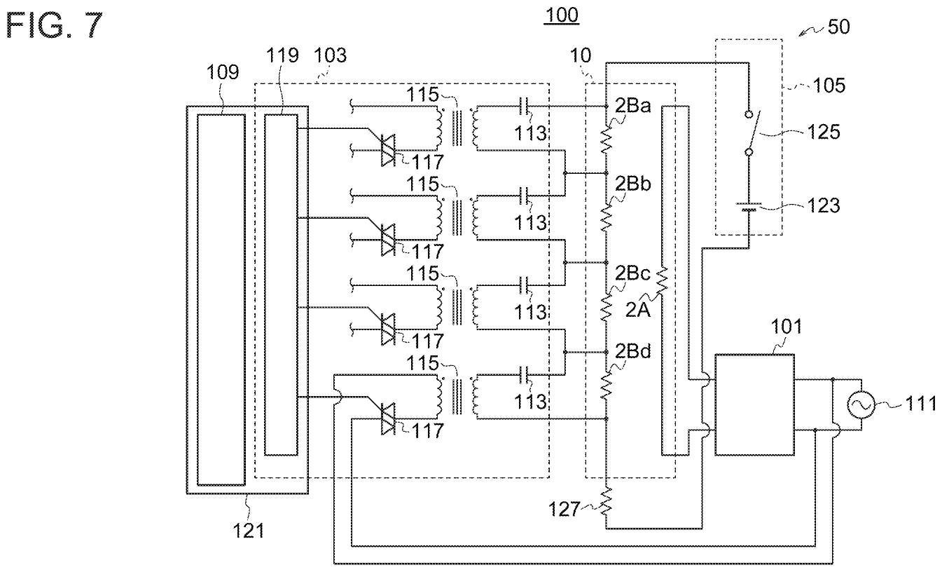

FIG. 7 is a circuit diagram showing an example of the hardware configuration for the portions mainly concerned with the power supply among the various functional parts shown in FIG. 6.

(First Driving Part)

The first driving part 101 is for example configured including a power supply circuit and computer (for example IC). Further, the first driving part 101 converts power supplied from a commercial power source 111 (or not shown power supply circuit) to a DC power or AC power having a suitable voltage and supplies the power to the first resistance heating element 2A (power supply parts at its two ends).

The power supplied from the commercial power source 111 is for example AC power having a frequency of 50 Hz to 60 Hz and a voltage of 200V. In a case where the power supplied by the first driving part 101 to the first resistance heating element 2A is the AC power, the frequency of this AC power may be lower, equal, or larger relative to the frequency of the commercial power source 111.

The control carried out by the first driving part 101, for example, as already explained, is feedback control based on an actual temperature (detection temperature) of the heater body 10a. However, the control carried out by the first driving part 101 may be open-loop control without feedback as well. This is because the temperature in the area Ar is controlled also by heat generation of the second resistance heating elements 2B. Note that, it is regarded that the case where the feedback control of the temperature by the second driving part 103 is better in response than the control of the temperature by the first driving part 101 includes an aspect where open-loop control is carried out in the first driving part 101.

The method of feedback control carried out by the first driving part 101 may be a known suitable one. For example, the control may be proportional control, may be PD control, may be PI control, may be PID control, or may be integral control. Further, for example, the control may be ON-OFF control supplying power when the detection value does not reach the target value and suspending the supply of power when it reaches the target value. When integral control is employed as the control method, for example, it is easy to make the response lower than the temperature control by the second resistance heating elements 2B.

The power of the first driving part 101 may be adjusted by a suitable method. For example, the power may be increased or decreased by so-called chopper control. The chopper control changes the effective value of the power by repeatedly turning on and off the supply of power in a relatively short cycle (usually a constant cycle) and changing the duty (the ratio of the ON period occupied in the cycle). Further, for example, the power may be increased/decreased by changing the voltage by a transformer as well.

(Second Driving Part)

The second driving part 103, for example, in the same way as the first driving part 101, converts the power supplied from a commercial power source 111 (or not shown power supply circuit) to a DC power or AC power having a suitable voltage and supplies the power to the plurality of second resistance heating elements 2B.

In the explanation of the present embodiment, a case where the second driving part 103 supplies AC power to the second resistance heating elements 2B will be taken as an example. The frequency of this AC power may be suitably set. For example, the frequency of the AC power may be lower than, equal to, or higher than the frequency of the commercial power source 111 or the frequency of AC power in the case where the first driving part 101 outputs the AC power. When it is equal to the frequency of the commercial power source 111, for example, the frequency need not be converted, therefore the configuration of the second driving part 103 can be made simple. Further, loss of power accompanying conversion of the frequency does not occur either.

The second driving part 103, for example, has a capacitor 113, transformer 115, and thyristor 117 for each of the second resistance heating elements 2B. Further, the second driving part 103 has a drive control part 119 which controls the operations of the thyristors 117.

The capacitor 113, transformer 115, and thyristor 117 are interposed between the commercial power source 111 and the second resistance heating element 2B. Note that, in FIG. 7, for convenience, the connection with the commercial power source 111 is shown only for the thyristor 117 corresponding to the second resistance heating element 2Bd. The same is true also for the connections with the commercial power source 111 for the thyristors 117 corresponding to the other second resistance heating elements 2B.

The capacitor 113 is connected in series between the second resistance heating element 2B and the commercial power source 111 (in more detail, the transformer 115). Due to the provision of such a capacitor 113, for example, the AC power from the transformer 115 can flow to the second resistance heating element 2B, while the possibility of an unwanted DC component flowing to the second resistance heating element 2B or transformer 115 can be reduced. The structure and material of the capacitor 113 may be various known ones. Further, the capacitance (impedance) may be suitably set.

The transformer 115 is for example configured by an isolation transformer and is interposed between the commercial power source 111 and the second resistance heating element 2B. Due to the provision of such a transformer 115, for example, the possibility of the component of the frequency which is higher than the frequency of the AC power supplied to the second resistance heating element 2B (noise) flowing to the second resistance heating element 2B can be reduced.

The transformer 115 (isolation transformer) is isolated between a primary side (coil) and a secondary side (coil). The transformer 115 may be configured so that not only are the primary side and the secondary side isolated, but also the isolation between the primary side and the secondary side is improved by arrangement of a shield or the like (may be an isolation transformer in a narrow sense as well). The structure and material etc. of the transformer 115 may be the same as various known ones.

The transformer 115, in the present embodiment, is one unable to change a transformation ratio. The transformation ratio is constant. Otherwise, the transformer 115 may be one able to change the transformation ratio as well. In the present embodiment, however, the second driving part 103 does not change the transformation ratio of the transformer 115 so as to make the temperature of the heater body 10a follow the target temperature. That is, the transformation ratio of the transformer 115 is constant regardless of the temperature of the heater 10. However, even if it is constant regardless of the temperature, naturally the fluctuation of error accompanying a temperature change may occur.

The transformation ratio of the transformer 115 may be less than 1, may be 1, or may exceed 1. Other parameters (for example inductance (impedance)) may be suitably set as well.

The thyristor 117 is utilized for adjusting the power which is supplied from the commercial power source 111 to the second resistance heating element 2B (in more detail, the transformer 115) according to the chopper control. The thyristor 117 is configured by for example a reverse-blocking three-terminal thyristor (thyristor in a narrow sense), reverse conducting thyristor, or bidirectional triode thyristor (TRIAC). Note that, in this way, in the present disclosure, the term of the “thyristor” is used in a broad sense unless it will be particularly explained otherwise. The structures and materials of these various thyristors may be various known ones.

The reverse-blocking three-terminal thyristor can carry current (for example either of positive or negative AC or DC) in only one direction (defined as the first direction). It can permit or block the flow of current in the first direction (the current in a reverse direction is always blocked). Specifically, the reverse-blocking three-terminal thyristor basically blocks the flow of current (first direction) when being supplied with voltage in the first direction and permits the flow of current (first direction) when an ON operation is carried out. After that, the reverse-blocking three-terminal thyristor maintains the state where the flow of the current (first direction) is permitted for a period in which application of voltage in the first direction continues even when the ON operation is suspended. In other words, when application of voltage in the first direction is suspended (for example when the AC voltage reverses in sign), the flow of the current in the first direction is blocked again.

The reverse conducting thyristor can carry current in two directions (AC). It can permit or block the flow of the current of one direction (determined as the first direction) between two directions (the other current between the two directions is permitted all the time). Further, the reverse conducting thyristor basically blocks the flow of the current (first direction) when being supplied with the voltage in the first direction and permits the flow of the current (first direction) when an ON operation is carried out. After that, the reverse conducting thyristor maintains the state where the flow of the current (first direction) is permitted for a period where application of voltage in the first direction continues even when the ON operation is suspended. In other words, when application of voltage in the first direction is suspended (for example when the AC voltage reverses in sign), the flow of the current in the first direction is blocked again.

The bidirectional triode thyristor can carry the current in two directions (AC) and can permit or block each of the flows of current in two directions. In the present embodiment, the bidirectional triode thyristor will be taken as an example as the thyristor 117. A specific operation of the bidirectional triode thyristor will be explained later.

The drive control part 119 is for example configured by a computer 121. The computer 121 is for example configured by combination of an IC and PC. This computer 121 for example configure not only the drive control part 119, but also the control part 109.

The drive control part 119, for example, controls the thyristor 117 (from another viewpoint, the power supplied from the thyristor 117 to the second resistance heating element 2B) so that an actual temperature (detection temperature) in the area Ar converges to the target temperature tp0 for each area Ar. The method of this feedback control may be a suitable known one in the same way as the control of the first driving part 101. For example, use may be made of proportional control, PD control, PI control, PID control, or ON-OFF control. Note that, when PID control is employed as the control method, for example, the temperature control can be highly precisely carried out by reducing overshoot and steady-state deviation and the like.

(Third Driving Part)

The third driving part 105, in the present embodiment, mainly supplies power to the plurality of second resistance heating elements 2B when utilizing the plurality of second resistance heating elements 2B as the thermistor. The third driving part 105 for example has a DC power supply 123 and a switch 125 which controls supply and suspension of the power from the DC power supply 123 to all of the plurality of second resistance heating elements 2B.

The DC power supply 123, for example, although not particularly shown, converts the AC power supplied from a commercial power source 111 to the DC power and supplies the result to the plurality of second resistance heating elements 2B. Further, the DC power supply 123, although not particularly shown, is configured including a constant current circuit. Accordingly, when the resistance values of the plurality of second resistance heating elements 2B change due to the temperature change, in the plurality of second resistance heating elements 2B, the current basically does not change and the voltage changes. That is, the temperature change appears in the voltage in the plurality of second resistance heating elements 2B. Note that, in the DC power supply 123, the configurations of the circuit for converting the AC power from the commercial power source 111 to the DC power and the constant current circuit may be made the same as various known ones.

The switch 125, for example, permits or suspends the supply of power from the DC power supply 123 to all of the plurality of second resistance heating elements 2B in response to the control signal which is input. Due to this, power can be supplied from the DC power supply 123 to the second resistance heating elements 2B at any timing. For example, as will be explained in detail later, at the timing when power is not supplied from the second driving part 103 to the plurality of second resistance heating elements 2B, power can be supplied from the DC power supply 123 to the plurality of second resistance heating elements 2B. As a result, for example, the resistance value (temperature) of the second resistance heating elements 2B can be detected based on only the power supplied from the DC power supply 123 to the second resistance heating elements 2B. The switch 125 may be configured by a transistor or another various known switches.

(Auxiliary Resistor)

For supply of power from the third driving part 105 to the plurality of second resistance heating elements 2B, an auxiliary resistor 127 is connected in series with respect to the plurality of second resistance heating elements 2B.

This auxiliary resistor 127 is for example utilized for confirmation of the power supplied from the third driving part 105 to the plurality of second resistance heating elements 2B. This is a shunt in a broad sense. The auxiliary resistor 127 is for example configured by a material having a relatively small change of the resistance value with respect to temperature change (for example, compared with the material of the second resistance heating elements 2B) and/or the auxiliary resistor 127 is arranged in an environment where the temperature change is small. Accordingly, for example, the magnitude of the current supplied from the third driving part 105 is reflected in the magnitude of the voltage in the auxiliary resistor 127 basically without being influenced by the temperature change.

Note that, the resistance value of the auxiliary resistor 127 is set smaller than the resistance value of the plurality of second resistance heating elements 2B. For example, the resistance value of the auxiliary resistor 127 is 1/1000 or less of the resistance value of all of the plurality of second resistance heating elements 2B. Due to this, the influence of the auxiliary resistor 127 exerted upon the heat generation by the plurality of second resistance heating elements 2B is made small.

The auxiliary resistor 127 may be provided in the drive device 50 or may be provided in the heater 10. When it is provided in the drive device 50, for example, the influence of the temperature of the heater 10 exerted upon the auxiliary resistor 127 can be reduced. Further, the configuration of the heater 10 can be simplified. The auxiliary resistor 127 may be grasped as a portion of the third driving part 105 or the temperature measurement part 107.

(Hardware Configuration According to Temperature Measurement)

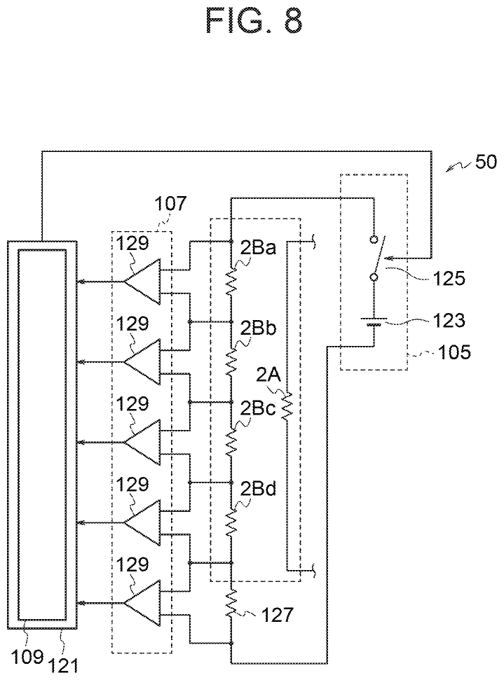

FIG. 8 is a circuit diagram showing details mainly for the parts concerned with temperature measurement among the various functional parts shown in FIG. 6 from the viewpoint of the hardware configuration.

(Temperature Measurement Part)

The temperature measurement part 107, for example, has a differential amplifier 129 for each of the second resistance heating elements 2B. Each differential amplifier 129 is connected to the power supply parts P at the two sides of the second resistance heating element 2B corresponding to itself. It outputs a signal having a signal strength (for example voltage) in accordance with the potential difference of those two power supply parts P to the control part 109 (computer 121). Due to this, as will be understood from the already given explanation, the temperatures of the second resistance heating elements 2B are measured.

Further, the temperature measurement part 107 has a differential amplifier 129 for the auxiliary resistor 127 as well. The differential amplifier 129 is connected to the two sides of the auxiliary resistor 127 and outputs a signal having a signal strength in accordance with the potential difference between the two sides of the auxiliary resistor 127 to the control part 109 (computer 121). Due to this, as will be understood from the already given explanation, it is confirmed whether the predetermined current is supplied to the plurality of second resistance heating elements 2B by the third driving part 105.

Note that, although not particularly shown, in order to protect an element (for example differential amplifier 129) in the temperature measurement part 107 or reduce the influence of the element in the temperature measurement part 107 exerted upon the power to be supplied to the second resistance heating elements 2B, an element and/or route for voltage division and/or diversion may be suitably provided. Further, a filter for removing noise from the signal input to the temperature measurement part 107 or the signal output from the temperature measurement part 107 may be provided as well.

(Control Part)

The control part 109, as already explained, is configured by the computer 121. The control part 109 performs control of the switch 125 in the third driving part 105. Further, the control part 109 samples the signals from the differential amplifiers 129 in a period where the switch 125 is made ON (period where power is supplied from the third driving part 105 to the plurality of second resistance heating elements 2B). Further, the control part 109 converts the signal strengths of the sampled signals (from another viewpoint, the resistance values of the second resistance heating elements 2B) to temperatures. Due to this, the temperatures in the areas Ar are acquired.

Note that, as the method of conversion from a resistance value to temperature (computation method), various known methods may be utilized. For example, computation identifying the temperature from the resistance value may be one using a mathematical equation or may be one using a map linking the resistance values and the temperatures. Further, the computation may include correction for removing a difference between the temperature of the second resistance heating element 2B and the temperature of the upper surface 10c as well.

The control part 109 acquiring the temperature in each area Ar outputs a signal including the information of the temperature to the drive control part 119 in the second driving part 103. Due to this, the drive control part 119 becomes able to perform feedback control of the temperature for each area Ar. Further, the control part 109 for example outputs the information of the temperature of the area Ar having the highest temperature or the information of a mean temperature of the upper surface 10c obtained from the temperatures of the plurality of areas Ar to the first driving part 101. Due to this, the first driving part 101 becomes able to perform feedback control of the temperature based on the temperature of the area Ar having the highest temperature or the mean temperature of the upper surface 10c.

Note that, the allocation of roles between the control part 109 and the other functional parts (101, 103, 105, and 107) may be suitably changed. For example, in the case where feedback control of the temperature by the first resistance heating element 2A is carried out so as to converge to the provisional target temperature which is lower than the target temperature tp0 by the predetermined temperature difference, the temperature utilized for feedback (the temperature obtained by subtracting the above predetermined temperature difference from the detection temperature) may be calculated not by the first driving part 101, but by the control part 109. Further, for example, the area Ar having the highest temperature may be specified or the mean temperature of the plurality of areas Ar may be calculated not in the control part 109, but in the first driving part 101.

The parameters of the target temperature tp0 and/or provisional target temperature and the like are for example set by operation of a not shown input device by the user. The input device may be made the same as various known ones. For example, it may be a switch which outputs a signal in accordance with a rotation position of a knob or maybe a touch painel. Further, the provisional target temperature may be set by the control part 109 based on the target temperature tp0 as well. For example, the provisional target temperature may be set by multiplying the target temperature tp0 by a predetermined coefficient (less than 1) or subtracting a predetermined constant from the target temperature tp0.

In the feedback control carried out by the first driving part 101 and the second driving part 103, compensation processing with respect to a change of resistivity along with a temperature change may be carried out as well. For example, the gain may be adjusted based on the temperature change as well. Due to this, further precise temperature control becomes possible.

(Timing of Temperature Measurement)

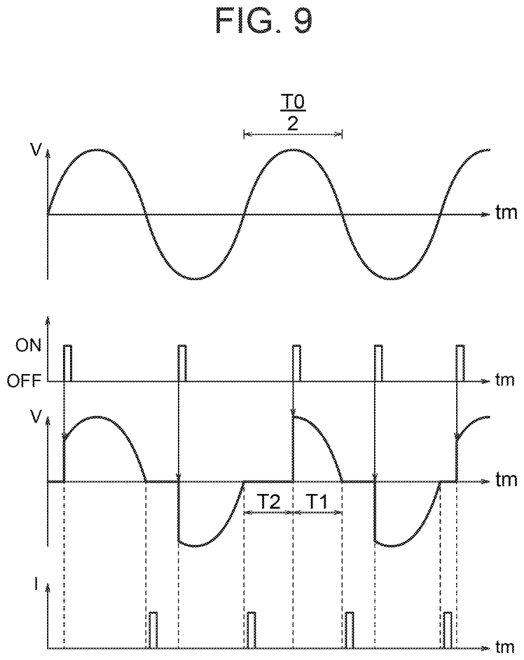

FIG. 9 are schematic timing charts for explaining the measurement method of the temperature. In the four graphs shown in FIG. 9, the abscissas show the times tm.

The graph in the uppermost part in FIG. 9 shows a change along with time of the AC voltage supplied from a commercial power source 111 (or not shown power supply circuit) to the second driving part 103. In this, the ordinate shows the voltage. The AC voltage for example inverts in sign (positive/negative) in a half cycle (T0/2). Here, as the AC voltage, a voltage changing in a curve (sine wave shaped one) is exemplified. However, the AC voltage may be one which is not sine wave shaped (for example is a rectangular wave, triangular wave, or sawtooth wave) as well. The maximum value (positive) and minimum value (negative) of the AC voltage are for example equal to each other in the potential difference from the reference potential. However, the two may be different as well.

The graph in the second part from the top in FIG. 9 shows the change along with time of the input operation with respect to the thyristor 117. In this, the ordinate shows the ON/OFF state of the input operation. That is, in the same graph, the point of time when the rectangular wave rises indicates the point of time when the current is made to flow to the gate of the thyristor 117 in order to render the thyristor 117 the conductive state.

The graph in the third part from the top in FIG. 9 shows the change along with time of the voltage supplied from the second driving part 103 to the second resistance heating element 2B. In this, the ordinate shows the voltage. The thyristor 117 becomes a conductive state when an ON operation is carried out. After that, the thyristor 117 maintains the conductive state even if the ON operation is suspended. Further, when the sign of the AC voltage is inverted, the thyristor 117 becomes a non-conductive state. As a result, the AC voltage supplied to the thyristor 117 (graph in the uppermost part in FIG. 9) is converted to a voltage having a waveform as shown in the graph in the third part in FIG. 9. The result is supplied to the second resistance heating element 2B.

Specifically, the voltage supplied from the thyristor 117 to the second resistance heating element 2B forms a waveform that repeats the supply and suspension of the power. The sum of a first period T1 where the power is supplied and a second period T2 where the supply of the power is suspended is a half cycle T0/2 of the AC voltage and is constant. The first period T1 to the second period T2 is switched at the point of time when the polarity of the voltage supplied to the thyristor 117 is inverted (point of time of crossing zero). On the other hand, the second period T2 is basically switched to the first period T1 at the time when the voltage supplied to the thyristor 117 is not zero.

By changing the ratio occupied in the semi cycle T0/2 by the first period T1 (duty: T1/(T0/2)) by an operation with respect to the thyristor 117, the effective value of the power is adjusted. That is, chopper control is carried out. The drive control part 119 in the second driving part 103 performs feedback control of the temperature by changing the duty in accordance with the detection temperature.

The graph in the lowermost part in FIG. 9 shows the change along with time of the current output by the third driving part 103. In this, the ordinate shows the current I. As shown in this graph, the control part 109 controls the switch 125 in the third driving part 105 so that the power is supplied from the third driving part 105 to the plurality of second resistance heating elements 2B in the second period T2 where the supply of power with respect to the second resistance heating elements 2B is suspended. Due to this, the voltages in the second resistance heating elements 2B due to only the power from the third driving part 103 are detected by the differential amplifiers 129.

The timing etc. in more detail for supplying power from the third driving part 105 to the plurality of second resistance heating elements 2B may be suitably set. For example, the timing of start of supply of the power is set using the point of time of start of the second period T2 as the standard. Note that, the point of time of start of the second period T2 is the point of time of the AC power supplied from a commercial power source 111 to the plurality of second resistance heating elements 2B crossing zero, therefore is common among the plurality of second resistance heating elements 2B. The time difference (including 0) from the point of time of start of the second period T2 up to the timing of the start of supply of the power from the third driving part 105 is for example set so as to become constant among the plurality of second periods T2. Further, for example, the time length of supply of the power and the current (current value) are set the same as each other among the plurality of second periods T2 as well. The specific values of the above time difference, time length, and current value may be suitably set in accordance with the specific configuration of the heater system 100.

Further, for example, the temperature measurement (acquisition of the voltage from the differential amplifier 129) is all carried out in the second period T2. In other words, the half cycle T0/2 of the AC voltage is made a sampling cycle for measuring the temperature. However, the sampling cycle may be made 2 or other higher whole multiple of the half cycle T0/2 as well.

The detection temperature utilized for the feedback control may be the value for each sampling cycle as it is, may be a mean value of the temperatures detected over a predetermined number of times, or may be one obtained by filtering by a filter (for example digital filter). The mean value may be a value where the periods for finding the mean value do not overlap each other among the plurality of mean values or may be such a moving average where the above periods overlap each other among the plurality of mean values. By using the mean value and/or filtered value in this way, noise can be removed.

(Method of Manufacturing Heater)

The method of manufacturing the heater 10 is for example as follows.

First, ceramic green sheets forming the first ceramic layer 1a to fourth ceramic layer 1d are prepared by the doctor blade method or another known method. The green sheets are formed to substantially constant thicknesses. Next, the green sheets are laser processed and/or punched using a die so as to obtain desired shapes. At this time, for example, holes where the connection conductors 3 and terminals 5 are to be arranged are formed.

Next, a metal paste for forming the second resistance heating elements 2, connection conductors 3, wiring 4, terminals 5, etc. is arranged on the green sheets by a screen printing or another suitable method. The material for forming the second resistance heating elements 2 and/or wiring 4 may be a conductive sheet including a conductive material and ceramic powder as well. The conductive sheet is for example sandwiched by the green sheets at the time of preparation of a laminate of the green sheets which will be explained later. Further, a groove may be formed in a green sheet and a conductive sheet may be arranged in this groove. Further, the material for forming the connection conductors 3 and/or terminals 5 may be the same as those of the connection conductors 3 and/or terminals 5 after completion. That is, the material may be a solid and columnar shaped metal (metal bulk material) as well.

Next, the green sheets are laminated to prepare a laminate of the green sheets. Further, the laminate of the green sheets is fired matching with the firing conditions of principal ingredients. Due to this, a sintered body (base body 1) provided with the second resistance heating elements 2, connection conductors 3, wiring 4, and terminals 5 in the internal portion can be obtained.

A plasma treatment-use table or electrostatic chuck can be also prepared by sandwiching a metal paste, metal plate, or metal mesh for forming plasma treatment-use electrodes or electrostatic chuck-use electrodes other than the second resistance heating elements 2, connection conductors 3, wiring 4, and terminals 5 at the time of lamination.

As described above, the heater 10 has the base body 1, first resistance heating element 2A, and plurality of second resistance heating elements 2B. The base body 1 is an insulating member which has a first surface (upper surface 10c). The first resistance heating element 2A extends along the upper surface 10c in the internal portion or on the surface of the base body 1 (internal portion in the present embodiment). The second resistance heating elements 2B are positioned on the upper surface 10c side or the side opposite to the upper surface 10c relative to the first resistance heating element 2A (opposite side to the upper surface 10c in the present embodiment) and extend along the upper surface 10c in the internal portion or on the surface of the base body 1 (internal portion in the present embodiment).

Accordingly, for example, the temperature of the upper surface 10c can be locally controlled by the plurality of second resistance heating elements 2B. Further, for example, because of provision of the first resistance heating element 2A, the amounts of heat generated by the plurality of second resistance heating elements 2B can be reduced. As a result, for example, the various components (for example connection conductors 3, wiring 4, terminals 5, capacitors 113, transformers 115, and thyristors 117) connected to the second resistance heating elements 2B may be reduced in size or the withstand voltage may be made low. The number of these components increases along with the increase of number of the second resistance heating elements 2B. Accordingly, for example, even if the heater 10 as a whole or the heater system 100 as a whole seems to cause an increase of size or an increase of cost at a glance due to the addition of the first resistance heating element 2A, but, in actuality, conversely it becomes easy to reduce the size or reduce the cost of the heater 10 as a whole or the heater system 100 as a whole due to the reduction of sizes or reduction of costs of the components relating to the plurality of second resistance heating elements 2B.

Further, in the present embodiment, the power supplied to the first resistance heating element 2A by the first driving part 101 is larger than the sum of power supplied by the second driving part 103 to the plurality of second resistance heating elements 2B.

In this case, for example, the effect of reducing the amount of heat generated by the plurality of second resistance heating elements 2B described above increases. In turn, for example, reduction of size or reduction of cost as heater 10 as a whole or the heater system 100 as a whole becomes easy.

Further, in the present embodiment, the first driving part 101 controls the temperature of the first resistance heating element 2A by the control of the power which is supplied to the first resistance heating element 2A. The second driving part 103 performs feedback control of the temperature of the second resistance heating elements 2B by control of the power which is supplied to the second resistance heating elements 2B for at least one (all in the present embodiment) of the plurality of second resistance heating elements 2B. The feedback control of the temperature by the second driving part 103 has a better response than the control of the temperature by the first driving part 101.

Accordingly, the possibility of divergence of the temperature of the heater 10 due to mutual interference between temperature control of the first resistance heating element 2A and temperature control of the second resistance heating elements 2B is reduced. Further, highly precise control making the actual temperature converge to the target temperature tp0 is carried out not by the first resistance heating element 2A covering over all of the upper surface 10c, but by the second resistance heating elements 2B which are locally arranged. As a result, a desired temperature distribution in all of the upper surface 10c is facilitated.

Further, in the present embodiment, provision is further made of the third driving part 105 which supplies power to between the pair of power supply parts P (P1 and P5) at the positions on the two sides of all of the plurality of second resistance heating elements 2B (third resistance heating element 2C).

Accordingly, for example, the temperature measurement can be carried out based on the resistance values of the second resistance heating elements 2B for the power of the third driving part 105. Further, for example, it becomes also possible to make all of the plurality of second resistance heating elements 2B generate heat by the power of the third driving part 105. If the power supplied to each of the plurality of second resistance heating elements 2B from the second driving part 103 is to be made larger, the sizes should be made larger or the withstand voltages should be made higher for various components which are connected to all of the plurality of first power supply part P1 to the fifth power supply part P5. However, in a case where the power to be supplied to all of the plurality of second resistance heating elements 2B is supplied by the third driving part 105, basically this can be realized by increasing the sizes or increasing the withstand voltages for only the components which are connected to the pair of power supply parts P (P1 and P5). As a result, reduction of the size or reduction of the cost of the heater 10 as a whole or the heater system 100 as a whole become easy.

Further, in the present embodiment, the second driving part 103 controls the power to be supplied to at least one (all in the present embodiment) predetermined second resistance heating element 23 among the plurality of second resistance heating elements 2B based on the resistance value of the predetermined second resistance heating element 2B.

That is, the second driving part 103 utilizes the second resistance heating elements 2B as thermistors and performs feedback control of the temperatures of the second resistance heating elements 2B. Accordingly, a dedicated sensor for detecting the temperature of the heater 10 need not be provided (however, an aspect where such a sensor is provided is also included in the art according to the present disclosure), so the configuration of the heater 10 can be simplified. The larger the number of second resistance heating elements 2B, the larger the effect.

Further, in the present embodiment, the second driving part 103 alternately repeats a first period T1 for supplying power to at least one (all in the present embodiment) predetermined second resistance heating element 2B and a second period T2 for suspending the supply of the power (note that, the durations of the first period T1 and the second period T2 are suitably set for each second resistance heating element 2B and each cycle). Further, the third driving part 105 supplies power to the predetermined second resistance heating elements 2B in at least a portion of the second period T2. The second driving part 103 controls the power to be supplied to the predetermined second resistance heating elements 2B based on the resistance values (directly the voltages in the present embodiment) of the predetermined second resistance heating elements 2B with respect to the power from the third driving part 105 in the second period T2.

Accordingly, for example, the resistance values of the second resistance heating elements 2B can be detected based on only the power supplied by the third driving part 105. The power supplied by the second driving part 103 is adjusted in accordance with the amounts of heat to be generated by the second resistance heating elements 2B. The resistance values can be detected at a timing where power is not supplied from the second driving part 103. Therefore, for example, the method of detection of the resistance values can be simplified. For example, as illustrated in the embodiment, a constant current is supplied to the second resistance heating elements 2B and the change of the resistance values can be detected as the change of the voltages. From another viewpoint, in the detection of the resistance values of the second resistance heating elements 2B, noise due to fluctuation of the power for the temperature control can be reduced.

Further, in the present embodiment, the cycle (T0/2) of the sum of the first period T1 and the second period T2 is constant.

In other words, the first period T1 and the second period T2 are the ON time and the OFF time in so-called chopper control. Accordingly, for example, the power supply to the second resistance heating elements 2B need not be suspended only for the temperature measurement (however, an aspect performing such control is also included in the art according to the present disclosure). Further, for example, the chopper control is carried out in a relatively short cycle, therefore the sampling cycle of the temperature measurement can be made short. In turn, the precision of temperature control is improved.

Further, in the present embodiment, the heater 10 has n+1 number of power supply parts P where “n” is an integer of 2 or more (n=4 in the present embodiment). The n+1 number of power supply parts P are positioned at n−1 number of midway positions (P2 to P4) in the single continuous third resistance heating element 2C and the positions (P1 and P5) at the two sides of the single continuous third resistance heating element 2C from these n−1 number of midway positions. Due to this, the single continuous third resistance heating element 2C is divided into “n” number of second resistance heating elements 2B. The third driving part 105 supplies power to between the pair of power supply parts P (P1 and P5) at the positions at the two sides described above. The second driving part 103 controls the power to be supplied to the second resistance heating elements 2B based on the resistance values of the second resistance heating elements 2B with respect to the power from the third driving part 105 in the second period T2 for each of the “n” number of second resistance heating elements 2B.

Accordingly, the plurality of second resistance heating elements 2B are respectively utilized as mutually different thermistors by the second driving part 103. On the other hand, the plurality of second resistance heating elements 2B are commonly given power for temperature measurement from the third driving part 105. Accordingly, the feedback control of local temperature is enabled, while the configuration for the temperature measurement is simplified.

Further, in the present embodiment, the second driving part 103 has the thyristors 117 and transformers 115. The thyristors 117 are interposed between the power supply part (commercial power source 111) outputting the AC power and the second resistance heating elements 2B and divide the half cycle T0/2 of the AC power into the first period T1 and the second period T2. The transformers 115 are interposed between the thyristors 117 and the second resistance heating elements 2B.

Accordingly, for example, since use is made of the thyristors 117, the chopper control can be carried out easily and cheaply. In a thyristor 117, a ripple arises when it becomes a conductive state. This ripple has a possibility of exerting an influence upon the control of the power to be supplied to the second resistance heating element 2B and/or the temperature measurement when the second resistance heating element 2B is utilized as the thermistor. However, due to the transformer 115 being interposed between the thyristor 117 and the second resistance heating element 2B, this ripple is evened out in at least part. As a result, the influence described above is reduced.

### Modification of First Embodiment

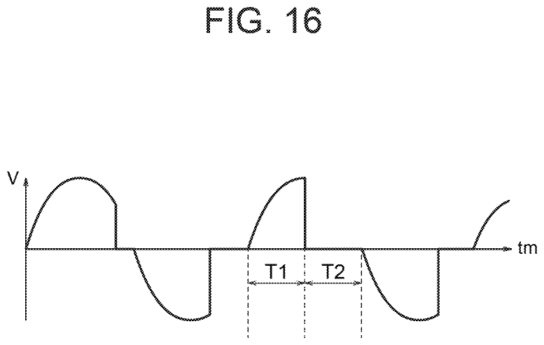

FIG. 16 is a view for explaining a modification of the first embodiment and corresponds to a part extracted from FIG. 9.

In FIG. 9, the timing of firing was made any timing, and the timing of extinguishing was made the timing of crossing zero. In other words, the chopper control was carried out by adjustment of the timing of firing. However, as shown in FIG. 16, the timing of firing may be made the timing of crossing zero, and the timing of extinguishing may be made any timing as well. That is, the chopper control may be carried out by adjustment of the timing of extinguishing as well. Further, the temperature measurement may be carried out in the second period T2 after the timing of the extinguishing up to the next zero cross timing. Note that, a circuit including a thyristor and realizing chopper control as shown in the view is known, therefore a detailed explanation of it will be omitted.

### Second Embodiment

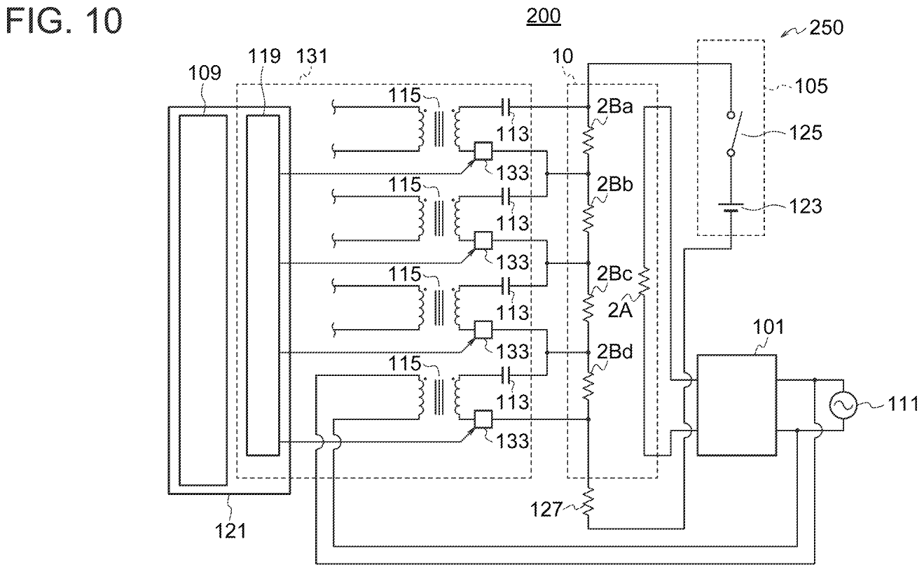

FIG. 10 is a view for explaining the configuration of a heater system 200 in a second embodiment and corresponds to FIG. 7 for the first embodiment.

The heater system 200 basically differs from the heater system 100 in the first embodiment only in the configuration of the second driving part. Specifically, a second driving part 131 in a drive device 250 in the present embodiment has solid state relays (below, simply referred to as “SSRs”) 133 in place of the thyristors 117 in the first embodiment.

Each SSR 133, for example, is connected in series to a second resistance heating element 2B on the second resistance heating element 2B side from the transformer 115. The structure and material of the SSR 133 maybe made various known ones. For example, the SSR 133 may be configured by a photo SSR including photo couplers. In this case, a signal is transferred as light, therefore the signal route is insulated, so it is difficult that the electrical noise is superposed on the signal.

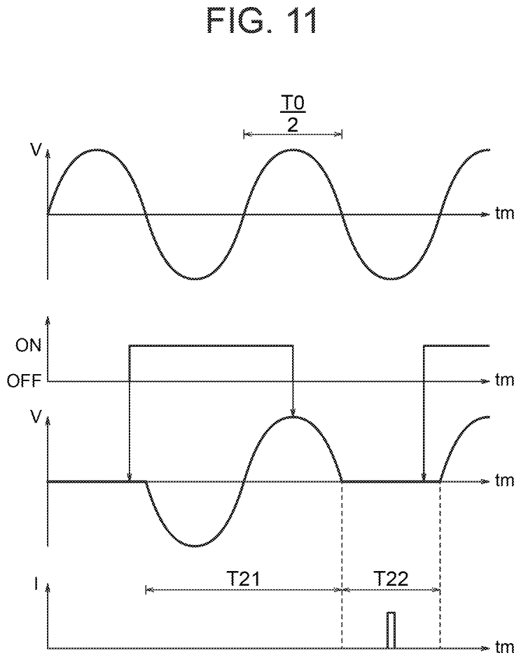

FIG. 11 are timing charts for explaining the operation of the drive device 250 and correspond to FIG. 9 for the first embodiment.

The four graphs in the same view, in order from the top, show a change along with time of an AC voltage supplied from a commercial power source 111 to the second driving part 103, a change along with time of an input operation with respect to a SSR 133, a change along with time of a voltage supplied from the second driving part 103 to a second resistance heating element 2B, and a change along with time of a current output by the third driving part 105. That is, in place of the operation of a thyristor 117 in FIG. 9 for the first embodiment, the operation of an SSR 133 are shown. The SSR 133 receives as input a predetermined input signal at the ON time.

An SSR 133 becomes a conductive state when it is turned ON and the voltage from the commercial power source 111 crosses zero (when sign is inverted). After that, the conductive state is maintained if the SSR 133 had been ON when the voltage from the commercial power source 111 crossed zero, while it is rendered a non-conductive state if it had been OFF when the voltage from the commercial power source 111 crossed zero. That is, the SSR 133 is made either of the conductive state or non-conductive state for each half cycle T0/2 of the AC voltage. As a result, the AC voltage output from the commercial power source 111 (the uppermost graph) is converted to a voltage having a waveform as shown in the graph in the third part in FIG. 11.

Specifically, the waveform of the voltage supplied from the SSR 133 to the second resistance heating element 2B becomes one repeating the supply of power and suspension of that. The duration of each of a first period T21 during which the power is supplied and a second period T22 during which the supply of power is suspended is “m” times (“m” is 1 or more) the half cycle T0/2 of the AC voltage unlike the first period T1 and second period T2 in the first embodiment. Further, “m” may be any number. Further, the effective value of the power is adjusted according to the ratio of the first period T21 and the second period T22. That is, chopper control is carried out. The drive control part 119 in the second driving part 131 performs feedback control of the temperature by changing the ratio of the first period T21 and the second period T22 in accordance with the detection temperature.

Note that, the sum of the first period T21 and the second period T22 need not be constant unlike the first embodiment. However, the sum may be made constant as well. From another viewpoint, in the same way as the first embodiment, the effective value of the power may be controlled by the duty ratio with respect to the constant cycle. For example, when the AC power is 50 Hz, when the sum of the first period T21 and the second period T22 is made about 2 seconds, the AC power is adjusted in 100 stages.

As shown in the lowermost graph in FIG. 11, the control part 109, in the same way as the first embodiment, controls the switch 125 in the third driving part 105 so that power is supplied from the third driving part 105 to the plurality of second resistance heating elements 2B in the second period T22 during which the supply of power to the second resistance heating elements 2B is suspended. Due to this, the voltage in the second resistance heating element 2B due to only the power from the third driving part 105 is detected by the differential amplifier 129.

The more detailed timing etc. for supplying power from the third driving part 105 to the plurality of second resistance heating elements 2B may be suitably set. For example, the timing of start of supply of the power is set using the point of time of start of the second period T22 as the standard. The time difference (including 0) thereof is for example constant among the plurality of second periods T22. Further, for example, the time length of supplying the power and the current (current value) are the same as each other among the plurality of second periods T22. The time difference, time length, and current value described above may be suitably set in accordance with the specific configuration of the heater system 200.

Note that, in the present embodiment, the second period T22 has at least a length of a half cycle T0/2 of the AC voltage unlike the first embodiment. Accordingly, as in the example shown, the temperature measurement may be carried out in the vicinity of the center of the half cycle T0/2 as well.

The sampling cycle of the temperature measurement may be suitably set. For example, as described above, the sum of the first period T21 and the second period T22 may be made constant and the time length of this sum may be made the sampling cycle. That is, the sampling cycle may be set so that the timing of sampling reliably falls in the second period T22.

Further, for example, when the sum of the first period T21 and the second period T22 is not constant, the temperature measurement may be carried out by judgment of whether the period is the second period T22. In other words, the sampling cycle may fluctuate.

Further, for example, in a case where the sum of the first period T21 and the second period T22 is not constant and the sampling cycle is constant, at the time when the sampling cycle arrives, the SSR 133 may be turned OFF only in the half cycle T0/2 for the temperature measurement with a higher priority than the control of the SSR 133 for the temperature control. When the sampling cycle is sufficiently long compared with the half cycle T0/2, even if the second period T22 is forcibly provided for the temperature measurement, the influence of that second period T22 exerted upon the temperature control is small.

As described above, in the present embodiment, the second driving part 131 has an SSR 133. The SSR 133 is provided between the power supply part (commercial power source 111) outputting the AC voltage and at least one (all in the present embodiment) second resistance heating element. It performs switching between the first period T21 and the second period T22 when the AC power crosses zero.

Accordingly, for example, the switching timing between the first period T21 and the second period T22 coincides with the AC power crossing zero, therefore the possibility of occurrence of a ripple is low. In turn, the possibility of this ripple appearing as noise in the temperature measurement is reduced. Further, for example, compared with the case where use is made of the thyristors 117, the second period of suspension of power from the second driving part 103 to the second resistance heating elements 2B is easily made longer. As a result, for example, the control conditions of the switch 125 in the third driving part 105 can be loosened. Note that, a thyristor 117 has inexpensiveness and other merits compared with an SSR 133.

### Third Embodiment

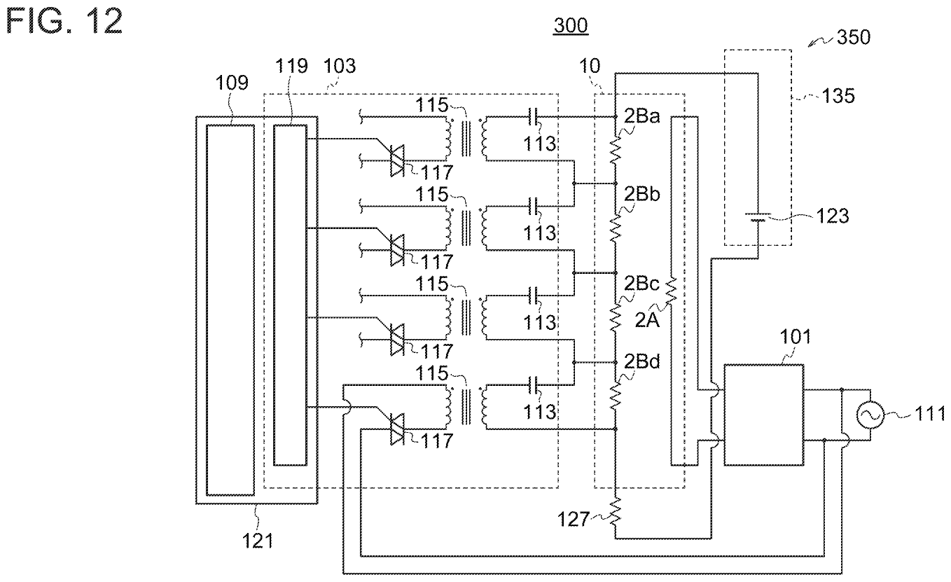

FIG. 12 is a view for explaining the configuration of a heater system 300 in a third embodiment and corresponds to FIG. 7 for the first embodiment.

The heater system 300 basically differs from the heater system 100 in the first embodiment only in the configuration of the third driving part. Specifically, a third driving part 135 in a drive device 350 in the present embodiment does not have the switch 125 in the first embodiment. That is, the power from the DC power supply 123 is supplied to the plurality of second resistance heating elements 2B all the time for a term during which the heater system 300 performs a heating operation.

FIG. 13A give conceptual views showing the control method of the heater system 300 and correspond to FIG. 5A for the first embodiment.

In the present embodiment, the time for supply of the power from the DC power supply 123 to the plurality of second resistance heating elements 2B is long. Therefore, compared with the first embodiment, the influence of the amount of heat generated by the power from the DC power supply 123 exerted upon the temperature of the upper surface 10c is large. Therefore, in the present embodiment, control considering this influence is carried out. Specifically, this is as follows.

The graph on the left side in the upper part in FIG. 13A, in the same way as FIG. 5A, shows the temperature realized due to the first resistance heating element 2A. In the temperature control by the first resistance heating element 2A, for example, control which was referred to in the first embodiment making the temperature obtained by subtracting a predetermined temperature difference from the detection temperature converge to the provisional target temperature tp1 which is lower than the target temperature tp0 by the predetermined temperature difference is carried out. Further, this temperature difference is given a magnitude including the amount of rise of the temperature which rises due to the power from the DC power supply 123.

The graph on the right side in the upper part in FIG. 13A, in the same way as FIG. 5A, shows the amount of rise of the temperature realized due to the plurality of second resistance heating elements 2B. As indicated by the two types of hatchings in this graph, the amount of rise of the temperature realized due to the plurality of second resistance heating elements 2B becomes the sum of the amount of rise of the temperature realized by the power from the DC power supply 123 which is commonly supplied to the plurality of areas Ar and the amount of rise of the temperature realized by power from the second driving part 103 which is individually supplied to the plurality of areas Ar.

Further, as shown in the graph in the lower part in FIG. 13A, the temperature in each area Ar is realized by the total sum of the amount of heat by the power of the first driving part 101, the amount of heat by the power of the second driving part 103, and the amount of heat by the power of the third driving part 135. Further, the temperatures in all areas Ar converge to the target temperature tp0.

FIG. 13B shows the change along with time of the voltage which is supplied from the second driving part 103 to the second resistance heating elements 2B and the change along with time of the current output by the third driving part 105 and corresponds to a portion of FIG. 9 for the first embodiment.

As shown in this graph, in the present embodiment, regardless of the first period T1 and the second period T2, a constant current is supplied from the third driving part 135 to the second resistance heating elements 2B. However, the control part 109 samples signals from the differential amplifier 129 in the second period T2. That is, the temperature measurement, in the same way as the first and second embodiments, is carried out in the second period T2 during which power is not supplied from the second driving part 103 to the second resistance heating elements 2B.

Note that, in the first embodiment and second embodiment, for example, the current from the DC power supply 123 may be given a magnitude large enough to perform the temperature measurement. In the present embodiment, the current from the DC power supply 123, in the same way as the first embodiment and second embodiment, may be made a magnitude large enough to perform the temperature measurement or may be made larger than this to positively contribute to the heat generation of the second resistance heating elements 2B.

In the example shown, a configuration due to combination of the thyristors 117 in the first embodiment and the third driving part 135 in the present embodiment was illustrated. However, the SSRs 133 in the second embodiment and the third driving part 135 in the present embodiment may be combined as well.

<Modifications>

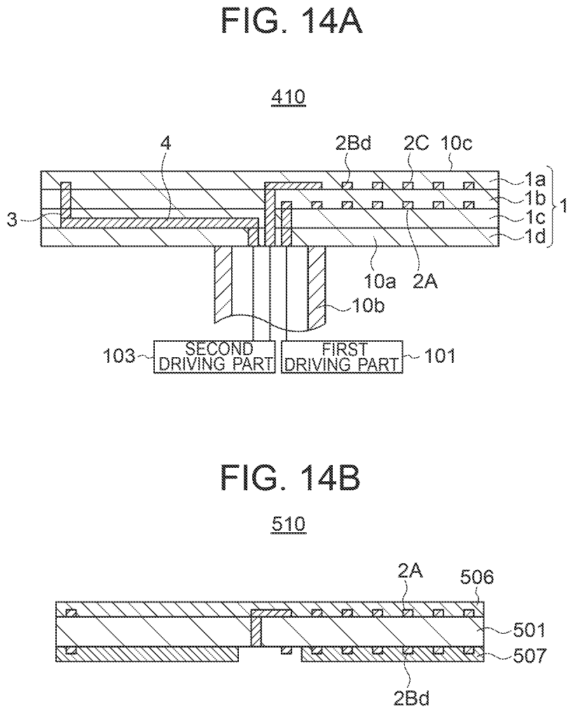

FIG. 14A and FIG. 14B are cross-sectional views showing the configurations of heaters according to modifications and correspond to FIG. 4.

In the above embodiments, the first resistance heating element 2A was arranged on the upper surface 10c side, and the plurality of second resistance heating elements 2B were arranged on the lower surface side. However, like the heater 410 shown in FIG. 14A, the positional relationships between the first resistance heating element 2A and the plurality of second resistance heating elements 2B may be made reverse relative to the above embodiments as well.

In this case, for example, the second resistance heating elements 2B are closer to the upper surface 10c than those in the above embodiments, therefore the precision of detection of the temperature on the upper surface 10c is improved. Note that, in the above embodiments, for example, compared with the modifications, the second resistance heating elements 2B having larger numbers of terminals 5 etc. than the first resistance heating element 2A are positioned on the lower surface side, therefore the configurations of the conductors in the base body 1 can be made simpler.

In the embodiments, the resistance heating elements 2 were buried in the base body 1 made of ceramic. However, like a heater 510 shown in FIG. 14B, the resistance heating elements 2 may be positioned on the surface of a base body 501 made of ceramic as well. In the example shown, the first resistance heating element 2A is positioned on the upper surface of the base body 501. Further, the second resistance heating elements 2B are positioned on the lower surface of the base body 501. Note that, only either of the first resistance heating element 2A or the second resistance heating elements 2B may be positioned on the surface of the base body 501.

In the example shown, the first resistance heating element 2A is covered by a coating layer 506 made of an insulation material different from the base body 501 (for example Y₂O₃, CaO, MgO, Al₂O₃, SiO₂, or another inorganic insulation material). In this case, the first resistance heating element 2A may be grasped as being buried in the base body by defining all of the base body 501 and coating layer 506 as the base body.

Further, in the example shown, the second resistance heating elements 2B are covered by a coating layer 507 made of an insulation material different from the base body 501 (for example Y₂O₃, CaO, MgO, Al₂O₃, SiO₂, or another inorganic insulation material). In this case, the second resistance heating elements 2B may be grasped as being buried in the base body by defining all of the base body 501 and coating layer 507 as the base body.

<Example of Application>

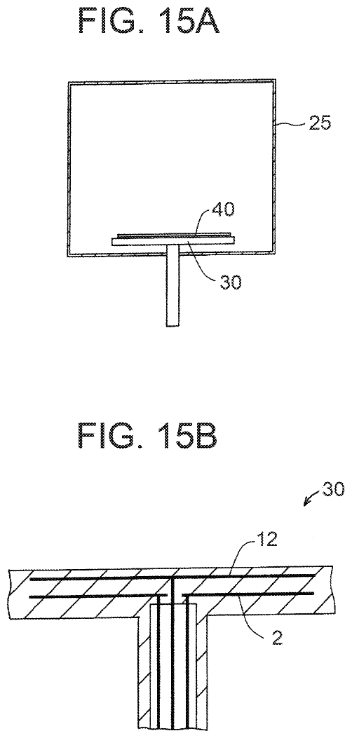

FIG. 15A is a view showing an example of application using the heater system in the present disclosure. FIG. 15A shows a situation where a heater 30 according to the present disclosure is provided in a chamber 25 in a semiconductor manufacturing device. On the upper surface of the heater 30, a wafer 40 is placed as the heated object.

FIG. 15B is a schematic view showing the configuration of the heater 30. The heater 30, for example, is given the same configuration as any of the heaters according to the various embodiments explained above or their modifications or a configuration obtained by adding an electrode 12 etc. to the above same configuration.

The electrode 12 is for example a plasma treatment-use electrode (for example RF (radio frequency) electrode). In this case, a system including the heater 30, drive device 50, and not shown drive device supplying voltage to the plasma treatment-use electrode configures a plasma treatment device.

Further, the electrode 12 is for example an electrostatic chuck-use electrode. In this case, the heater 30 configures the electrostatic chuck. Further, a system including the heater 30, drive device 50, and not shown drive device supplying voltage to the electrostatic chuck-use electrode configures an adsorption device.

Further, the heater 30 may be applied to a CVD manufacturing process in semiconductor manufacturing as well.

The art according to the present disclosure is not limited to the above embodiments and modifications etc. and may be made worked in various ways.

The adjustment of the power from the second driving part to the second resistance heating element is not limited to the chopper control. For example, it may be realized by adjustment of the voltage by a transformer as well. Further, in a case where the second resistance heating elements are utilized as thermistors, the third driving part need not be provided and the resistance values of the second resistance heating elements when supplying power from the second driving part to the second resistance heating elements may be detected.

In the above embodiments, only the second resistance heating elements were utilized as the thermistors. However, not only the second resistance heating elements, but also the first resistance heating element may be utilized as the thermistors. Further, the second resistance heating elements may be utilized as the thermistors, the first resistance heating element need not be utilized as a thermistor, and a sensor for detecting the temperature of the first resistance heating element may be provided. For example, the sensor may be provided at the position closer to the first resistance heating element than the plurality of second resistance heating elements as well.

In the above case, the amounts of heat of the second resistance heating elements may be controlled based on the temperatures detected by the second resistance heating elements used as the thermistors, while the amount of heat of the first resistance heating element may be controlled based on the temperature detected by the first resistance heating element used as the thermistor or the sensor described above. That is, the detection temperatures to be fed back may be separately measured between the first resistance heating element and the second resistance heating elements as well.

When the amount of heat of the first resistance heating element is controlled based on the temperature detected by the first resistance heating element used as the thermistor or the sensor described above, for example, control to the provisional target temperature explained in the above embodiments (the temperature lower than the target temperature) is carried out. In the heater, when the position of the first resistance heating element used as the thermistor or the sensor described above is a position where the temperature becomes lower than the positions of the second resistance heating elements used as the thermistors, according to a certain temperature difference between the target temperature and the provisional target temperature, the temperature of the first resistance heating element used as the thermistor or the above sensor may be used as it is for the feedback control of the first resistance heating element.

In the explanation of the above embodiments, a form of the SSR that does not become a conductive state even if it is turned ON unless crossing zero was taken as an example. However, the SSR may also be one becoming a conductive state when it is made ON, then being kept in the conductive state if it was ON at the time of crossing zero, while being rendered a non-conductive state if it has been OFF at the time of crossing zero. Further, the chopper control of the second driving part may be realized by elements other than the thyristors and SSR.

The contents of Patent Literatures 1 to 5 mentioned in the section on background art and the contents of Japanese Patent Application No. 2017-208184 applied to Japan Patent Office on Oct. 27, 2017 may be incorporated by reference in the present application.

### REFERENCE SIGNS LIST

1 . . . base body, 2A . . . first resistance heating element, 2B . . . second resistance heating element, 5 . . . terminal, 10 . . . heater, and 10c . . . upper surface (first surface).

1. A heater comprising:
an insulating base body comprising a first surface and a second surface facing the first surface,
a first resistance heating element which extends along the first surface in an internal portion or on a surface of the base body, and
a plurality of second resistance heating elements which are located on the first surface side or the second surface side relative to the first resistance heating element and extend along the first surface in the internal portion or on the surface of the base body.

2. The heater according to claim 1, comprising n+1 number of power supply parts dividing a single continuous resistance heating element into “n” number of the second resistance heating elements at n−1 number of midway positions in the single continuous resistance heating element and at positions at two sides of the continuous resistance heating element from the n−1 number of midway positions, “n” being an integer of 2 or more.

3. A heater system comprising:
the heater according to claim 1,
a first driving part which supplies power to the first resistance heating element, and
a second driving part which individually supplies power to the plurality of second resistance heating elements.

4. The heater system according to claim 3, wherein the power which is supplied by the first driving part to the first resistance heating element is larger than the sum of the power which is supplied by the second driving part to the plurality of second resistance heating elements.

5. The heater system according to claim 3, wherein:
the first driving part controls temperature of the first resistance heating element by control of the power which is supplied to the first resistance heating element,
the second driving part performs feedback control of temperature of the second resistance heating element for at least one of the plurality of second resistance heating elements, and
the feedback control of the temperature according to the second driving part is better in response than the control of the temperature according to the first driving part.

6. The heater system according to claim 3, wherein:
the first driving part performs control making the first resistance heating element generate an amount of heat making temperature of the heater converge to a predetermined provisional target temperature, and
the second driving part performs control making the second resistance heating element generate an amount of heat making temperature of the heater converge from the provisional target temperature to a target temperature which is higher than the provisional target temperature.

7. The heater system according to claim 3, further comprising:
n+1 number of power supply parts dividing a single continuous resistance heating element into “n” number of the second resistance heating elements at n−1 number of midway positions in the single continuous resistance heating element and at positions at two sides of the continuous resistance heating element from the n−1 number of midway positions, “n” being an integer of 2 or more, and
a third driving part which supplies power to between a pair of power supply parts at the positions on the two ends.

8. The heater system according to claim 3, wherein the second driving part controls the power to be supplied to at least one predetermined second resistance heating element among the plurality of second resistance heating elements based on the resistance value of the predetermined second resistance heating element.

9. The heater system according to claim 8, further comprising a third driving part which supplies power to the predetermined second resistance heating element, wherein
the second driving part alternately repeats a first period of supplying power to the predetermined second resistance heating element and a second period of suspending the supply of the power,
the third driving part supplies power to the predetermined second resistance heating element in at least a portion of the second period, and
the second driving part controls the power to be supplied to the predetermined second resistance heating element based on a resistance value of the predetermined second resistance heating element with respect to the power from the third driving part in the second period.

10. The heater system according to claim 9, wherein cycles each consisting of the sum of the first period and the second period are constant.

11. The heater system according to claim 9, wherein:
the heater comprises n+1 number of power supply parts, dividing a single continuous resistance heating element into “n” number of the second resistance heating elements at n−1 number of midway positions in the single continuous resistance heating element and at positions at two sides of the continuous resistance heating element from the n−1 number of midway positions, “n” being an integer of 2 or more,
the third driving part supplies power to between the pair of power supply parts at the positions on the two sides, and,
the second driving part controls the power to be supplied to the second resistance heating element based on a resistance value of the second resistance heating element with respect to power from the third driving part in the second period for each of the “n” number of second resistance heating elements.

12. The heater system according to claim 9, wherein the second driving part comprises
a thyristor which is interposed between a power supply part outputting an AC power and the predetermined second resistance heating element and divides a half cycle of the AC power to the first period and the second period, and
a transformer is interposed between the thyristor and the predetermined second resistance heating element.

13. The heater system according to claim 9, wherein the second driving part comprises a solid state relay which is interposed between a power supply part outputting an AC power and the predetermined second resistance heating element and performs switching between the first period and the second period at the time when the AC power crosses zero.
